(19) United States
(12) Patent Application Publication
(10) Pub. No.: US 2022/0259766 A1
(43) Pub. Date: Aug. 18, 2022

(54) INDIUM-GALLIUM-NITRIDE LIGHT EMITTING DIODES WITH INCREASED QUANTUM EFFICIENCY

(71) Applicant: Applied Materials, Inc., Santa Clara, CA (US)

(72) Inventors: Michael Chudzik, Mountain View, CA (US); Max Batres, Redwood City, CA (US); Michel Khoury, Santa Barbara, CA (US)

(73) Assignee: Applied Materials, Inc., Santa Clara, CA (US)

(21) Appl. No.: 17/176,367

(22) Filed: Feb. 16, 2021

(51) Int. Cl. C30B 29/40; H01L 21/02; C30B 33/08; H01L 33/00

(52) U.S. Cl. CPC C30B 29/406; H01L 21/02458; C30B 33/08; C30B 25/02; H01L 21/02505; H01L 33/0075; H01L 21/0254

(57) ABSTRACT

Exemplary methods of forming a semiconductor structure may include forming a nucleation layer on a semiconductor substrate. The exemplary methods may further include forming at least one gallium nitride (GaN)-containing region on the nucleation layer, and forming an indium-gallium-nitride (InGaN)-containing layer on the GaN-containing region. A porosified region may be formed on a portion of at least one of the GaN-containing region and the InGaN-containing layer, and an active region may be formed on the porosified region. In embodiments, the porosified region may be characterized by a void fraction of greater than or about 20 vol. %. In further embodiments, the active region may include a greater mole percentage (mol. %) indium than the porosified region or the GaN-containing region. In still further embodiments, the active region may characterized by a peak light emission at a wavelength of greater than or about 620 nm.

### TECHNICAL FIELD

The present technology relates to semiconductor processes and products. More specifically, the present technology relates to producing semiconductor structures and the devices formed.

### BACKGROUND

Integrated circuits are made possible by processes which produce intricately patterned material layers on substrate surfaces. Producing patterned material on a substrate requires controlled methods for deposition and removal of materials. However, with new device designs, producing high quality layers of material may be challenging.

Thus, there is a need for improved systems and methods that can be used to produce high quality devices and structures. These and other needs are addressed by the present technology.

### SUMMARY

Exemplary methods of forming a semiconductor structure may include forming a nucleation layer on a semiconductor substrate. The exemplary methods may further include forming a gallium nitride (GaN)-containing region on the nucleation layer, and forming a indium-gallium-nitride (InGaN)-containing layer on the GaN-containing region. In embodiments, a portion of at least one of the GaN-containing region and the InGaN-containing layer may be porosified to form a porosified region. The InGaN-containing layer may further include an active region on the porosified region. In embodiments, the active region may include a greater mole percentage (mol. %) indium than the porosified region.

In additional embodiments, the exemplary methods may include forming the GaN-containing region by selective area growth (SAG) of GaN-containing material on exposed portions of the nucleation layer. In still further embodiments, the GaN-containing region may be annealed to form a planar facet in the GaN-containing region. In some embodiments, the InGaN-containing layer may be formed on the planar facets of the annealed GaN-containing region. In still further embodiments, the porosified region may be formed by contacting the portion of the GaN-containing region and/or InGaN-containing layer with an electrochemical etchant.

In embodiments, the porosified region may be characterized by a void fraction of greater than or about 20 vol. %. In further embodiments, the active region may be characterized by an amount of indium greater than or about 30 mol. %. In still further embodiments, the active region may be characterized by a peak intensity of light emission at a wavelength of greater than or about 620 nm. In additional embodiments, the semiconductor formed by the exemplary method may be a light emitting diode characterized by an external quantum efficiency of greater than or about 0.2%.

Additional embodiments of the present technology may include semiconductor processing methods where a GaN-containing region is formed on a substrate. In embodiments, the methods may further include forming an InGaN-containing layer on the GaN-containing region. In further embodiments, a portion of at least one of the GaN-containing region and the InGaN-containing layer may be porosified to form a porosified region. The porosifed region may characterized by a void fraction of greater than or about 20 vol. %. In still additional embodiments, the methods may include forming an active region on the porosified region, where the active region may be characterized by a peak light emission at a wavelength of greater than or about 620 nm.

In further embodiments, the porosified region may be formed by electrochemically etching a silicon-doped region in at least one of the GaN-containing region and the InGaN-containing layer. In embodiments, the silicon-doped region may be characterized by an amount of silicon that is greater than or about 5×10¹⁷ atoms/cm³. In further embodiments, the silicon-doped region may be electrochemically etched with an etchant that includes an acid. In some embodiments, the acid etchant may be oxalic acid. In some further embodiments, the GaN-containing region may be formed by selective area growth and annealing of an as-deposited GaN-containing material.

Still additional embodiments of the present technology may include semiconductor structures. In embodiments, these structures may include at least one subpixel comprising a GaN-containing region in contact with a nucleation layer formed between the GaN-containing region and a substrate. The structures may further include a porous region in contact with the GaN-containing region. The structures may additionally include an active region in contact with the porous region. In embodiments, the active region may be characterized by an amount of indium greater than or about 30 mol. %.

In further embodiments, the nucleation layer of the semiconductor structure may include an aluminum nitride (AlN) layer, a niobium nitride (NbN) layer, a titanium nitride (TiN) layer, or a hafnium nitride (HfN) layer. In additional embodiments, the GaN-containing region may lack parallel sidewalls. In still further embodiments, the semiconductor structure may include a second subpixel that includes a second active region characterized by an amount of indium that is less than or about 25 mol. %, and may additionally include a third subpixel that includes a third active region characterized by an amount of indium that is less than or about 15 mol. %. In embodiments, the first active region may be characterized by a peak light emission at a wavelength of greater than or about 620 nm and an external quantum efficiency of greater than or about 0.2%. In still further embodiments, the semiconductor structure may be a light emitting diode (LED).

Such technology may provide numerous benefits over conventional semiconductor processing methods and structures. For example, embodiments of the processing methods may allow InGaN-containing active regions to be loaded with more indium without a proportional increase in the stress generated at the interface between the active regions and underlying porosified regions (e.g., compliant regions). Higher indium levels in the active region shift the peak intensity of light emitted by the region to longer wavelengths. Additionally, embodiments may include devices with increased quantum efficiencies for emitting light in the red-part of the visible spectrum that is characterized by wavelengths greater than or about 620 nm. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows exemplary operations in a method of forming semiconductor devices according to some embodiments of the present technology.

FIGS. 3A-3D show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Nitrides of Group III metals such as aluminum, indium, and gallium are promising materials for making light emitting diodes (LEDs) at micrometer scale (i.e., μLEDs). Unfortunately, the conversion efficiencies for these materials to translate the energy from electrical current into the emission of light is far from uniform across the visible spectrum. For example, indium-gallium-nitride-containing materials are significantly more efficient at converting energy from electrical current into blue-colored light than red-colored light. Consequently, a red-green-blue (RGB) pixel made from three subpixels of InGaN materials use balancing conditions that either increase the emission intensity of the red subpixel, decrease the intensity of the blue subpixel, or both. Additional balancing conditions for the green subpixel, which has a conversion efficiency intermediate between the blue and red subpixels, may also be used.

The differences in the conversions efficiencies of the RGB subpixels is caused in part by the different amounts of indium that need to be loaded into the InGaN-containing active region. The blue subpixel normally uses the least amount of indium in the active region (e.g., less than or about 15 mol. % indium), while the red subpixel normally uses a greater amount (e.g., greater than or about 30 mol. %). Increasing amounts of indium in the active region create more defects and stress due to mismatches in the lattice structure at the interface of the active region and an adjacent GaN-containing layer. The increased stress and defects in the indium-loaded active region provide more opportunities for the electrical current passing through the active region to be converted into phonons and heat instead of emitted light (i.e., photons). As a result, the conversion efficiency for converting the energy of the electrical current into emitted light may be significantly lower for the indium-loaded red subpixel compared to the indium-light blue subpixel.

One approach to increasing the conversion efficiency of InGaN-containing active regions with high amounts of indium is to form them on a porous intermediate layer (often called a compliant layer) positioned between the active region and the GaN-containing layer. The increased porosity in the compliant layer may reduce the amount of defects and stress created at the interface with the indium-loaded active region. In addition, the amount of porosity in the compliant layer can be adjusted based on the amount of indium in the active region: a red-light-emitting active region may be formed on a more porous InGaN compliant layer, while a blue-light-emitting active region may be formed on an InGaN layer with little or no added porosity. A green-light-emitting active region, with an intermediate amount of indium between the red- and blue-light-emitting active regions, may be formed on an InGaN layer of intermediate porosity.

While increasing the porosity in a compliant layer may reduce the defects and stress in the active region generated at the interface of the compliant layer and active region, it does not address defects at other surfaces of the active region. These other surfaces can include sidewalls formed in the active region by the patterned etching of a planar layer of active material into the mesa-shaped active regions of the RGB subpixels. The etching process can create many defects down the length of the sidewalls that can channel a significant portion of the electric current supplied to the active region into non-light emitting processes like phonon generation and heat. Consequently, top-down fabrication processes that subtractively etch portions of active and compliant layer material to form mesa-shaped subpixels are still characterized by low conversion efficiencies even after making the compliant layer porous.

Embodiments of the present technology address the problem of low conversion efficiency created by stress and defects in the active region of red-light-emitting subpixels by taking a bottom-up approach to the formation of the porosified and active regions. In embodiments, the GaN-containing regions may be selectively grown on a nucleation layer that is formed on a wafer substrate. The GaN-containing regions may be annealed to sublimate a portion of the GaN-containing material from the apex of the region to form a planar facet (sometimes called a c-facet) upon which the compliant layer may be formed. In additional embodiments, the GaN-containing region may include indium to better match the lattice structure and reduce the stress and defects in the InGaN-containing materials in the porosified and active regions.

In embodiments, the porosifed region formed in a portion of at least one of the GaN-containing region and the InGaN-containing layer may be formed before the active region. This permits a wider variety of porosification techniques to be used to make the porosified region more porous. It also permits greater variations in the porosity of the porosified region between the blue subpixels that may have little or no added porosity, and the red subpixels that may have more added porosity.

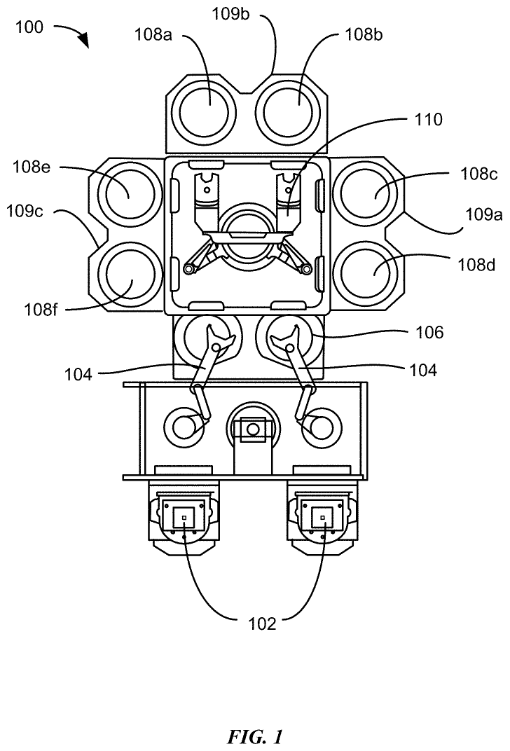

FIG. 1 shows a top plan view of one embodiment of a processing system 100 of deposition, etching, baking, and curing chambers according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

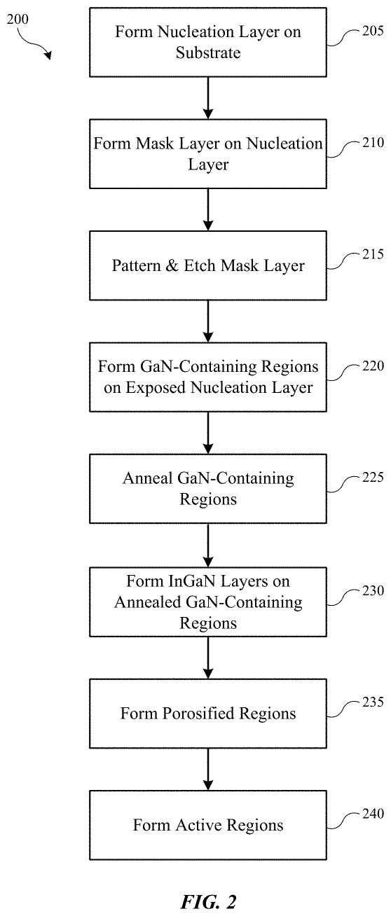

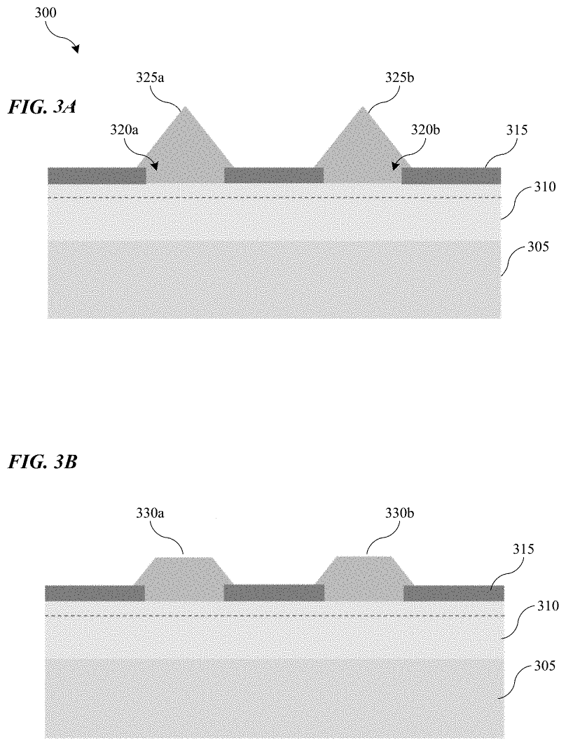

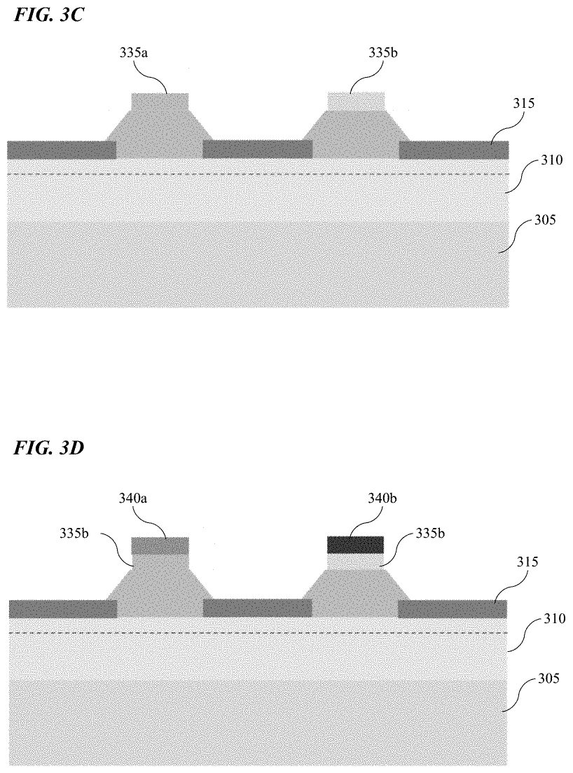

System 100, or more specifically chambers incorporated into system 100 or other processing systems, may be used to produce structures according to some embodiments of the present technology. FIG. 2 shows exemplary operations in a method 200 of forming a semiconductor structure according to some embodiments of the present technology. Method 200 may be performed in one or more processing chambers, such as chambers incorporated in system 100, for example. Method 200 may or may not include one or more operations prior to the initiation of the method, including front-end processing, deposition, etching, polishing, cleaning, or any other operations that may be performed prior to the described operations. The method may include a number of optional operations, which may or may not be specifically associated with some embodiments of methods according to the present technology. Method 200 describes operations shown schematically in FIGS. 3A-3D, the illustrations of which will be described in conjunction with the operations of method 200. It is to be understood that FIGS. 3A-3D illustrates only partial schematic views with limited details, and in some embodiments a substrate may contain any number of semiconductor sections having aspects as illustrated in the figures, as well as alternative structural aspects that may still benefit from any of the aspects of the present technology.

Method 200 may involve operations to develop the semiconductor structure to a particular fabrication operation. Although in some embodiments method 200 may be performed on a base structure, in additional embodiments the method may be performed subsequent other material formation. As illustrated in FIG. 3A, the semiconductor structure may represent a device 300 after front-end or other processing has been completed. For example, substrate 305 may be a planar material, or may be a structured device, which may include multiple materials configured as posts, trenches, or other structures as would be understood are similarly encompassed by the present technology. Substrate 305 may include any number of conductive and/or dielectric materials including metals, including transition metals, post-transition metals, metalloids, oxides, nitrides, and carbides of any of these materials, as well as any other materials that may be incorporated within a structure. In some embodiments, substrate 305 may be or include silicon, which may be doped by any number of materials, as well as silicon-containing or gallium-containing materials. The doping may be n+ or n− in some operations, and the silicon may be formed or grown by any number of techniques. Additionally, in embodiments, one or more doped regions may be included in the substrate. For example any number of n- or p-doping regions may be included on the substrate.

Embodiments of method 200 may include the formation of a nucleation layer 310 on the substrate 305 at operation 205. The nucleation layer provides a surface to form GaN-containing regions that would otherwise take too long to form, or not form at all, on the underlying substrate 305. In embodiments, the nucleation layer 310 may include one or more metal nitrides such as aluminum nitride, niobium nitride, titanium nitride, or hafnium nitride, among other types of nitrides. In some embodiments, the nucleation layer may include gallium nitride. In embodiments, the nucleation layer 310 may be formed by physical vapor deposition (PVD) of the nucleation layer on the substrate. In further embodiments, the nucleation layer 310 may be characterized by a thickness greater than or about 5 nm, greater than or about 10 nm, greater than or about 25 nm, greater than or about 50 nm, greater than or about 100 nm, greater than or about 250 nm, greater than or about 500 nm, greater than or about 750 nm, greater than or about 1000 nm, greater than or about 1250 nm, greater than or about 1500 nm, greater than or about 1750 nm, greater than or about 2000 nm, or more.

In further embodiments, method 200 may include the formation of a mask layer 315 on the nucleation layer 310 at operation 210. In embodiments, the mask layer 315 may be made from one or more dielectric materials such as silicon oxide, silicon nitride, silicon carbide, amorphous carbon, or silicon-oxy-carbide, among other dielectric materials. The mask layer 315 may be patterned and etched at operation 215 to form openings 320 in the mask layer 315 that permit the growth gallium-and-nitrogen containing materials on the exposed portions of the nucleation layer 310.

In embodiments, operation 215 may pattern openings 320 for the formation of a red, green, and blue subpixels that together constitute a pixel in a light-emitting-diode display. A longest dimension of the openings 320 may be less than or about 10 μm, less than or about 5 μm, less than or about 1 μm, less than or about 0.9 μm, less than or about 0.8 μm, less than or about 0.7 μm, less than or about 0.6 μm, less than or about 0.5 μm, less than or about 0.4 μm, less than or about 0.3 μm, less than or about 0.2 μm, less than or about 0.1 μm, or less.

Method 200 may further include the forming of GaN-containing regions 325a-b where the pattern openings 320 have exposed the nucleation layer 310. In embodiments, the operation 220 to form the GaN-containing regions 325a-b may include the metal-organic chemical vapor deposition (MOCVD) of GaN-containing material on the surfaces of the nucleation layer 310 exposed to the MOCVD precursors. In further embodiments, these precursors may include one or more alkyl gallium compounds such as trimethylgallium or triethylgallium to provide the gallium component of the GaN-containing material that forms the regions. In additional embodiments, the precursors may also include ammonia (NH₃) to provide the nitrogen component of the GaN-containing regions 325a-b.

In still further embodiments, the GaN-containing regions 325a-b may include one or more additional components such as aluminum and indium. In these embodiments, the MOCVD precursors may further include one or more organo-aluminum compounds such as trimethyl-aluminum. In additional embodiments, the precursors may further include one or more alkyl indium compounds such as trimethyl indium. In embodiments, the mole ratio of the one or more additional components may be less than or about 15 mol. %, less than or about 12.5 mol. %, less than or about 10 mol. %, less than or about 9 mol. %, less than or about 8 mol. %, less than or about 7 mol. %, less than or about 6 mol. %, less than or about 5 mol. %, or less. For example, the GaN-containing regions 325a-b may include indium at a level less than or about 15 mol. %, less than or about 14 mol. %, less than or about 13 mol. %, less than or about 12 mol. %, less than or about 11 mol. %, less than or about 10 mol. %, less than or about 9 mol. %, less than or about 8 mol. %, less than or about 7 mol. %, less than or about 6 mol. %, less than or about 5 mol. %, less than or about 4 mol. %, less than or about 3 mol. %, less than or about 2 mol. %, less than or about 1 mol. %, or less.

In embodiments, the mole ratio of the nitrogen to the gallium, and other Group III metals, in the GaN-containing regions 325a-b may be adjusted through the flow rate of the nitrogen-containing precursors and the gallium-containing precursors. In further embodiments, the flow rate ratio of the nitrogen-containing precursors to the gallium-containing precursors may be greater than or about 50, greater than or about 100, greater than or about 500, greater than or about 1000, greater than or about 5000, greater than or about 10000, greater than or about 20000, greater than or about 30000, or more.

In additional embodiments, the GaN-containing regions 325a-b may be formed at temperatures selected for the deposition of the precursors on the exposed areas of the nucleation layer 310. In embodiments, the deposition temperature may be characterized as greater than or about 500° C., greater than or about 600° C., greater than or about 700° C., greater than or about 800° C., greater than or about 900° C., greater than or about 1000° C., greater than or about 1100° C., or more. In some embodiments, the deposition temperature for an GaN-containing material may adjusted based on the amount of additional components that are present in the material. In embodiments, a GaN-containing material that includes a significant amount of indium may be formed at a deposition temperature that is lower than an indium-free GaN-containing material.

In additional embodiments, a GaN-containing material that further includes indium may be deposited at a deposition temperature less than or about 700° C., less than or about 650° C., less than or about 600° C., or less.

In further embodiments, the GaN-containing regions 325a-b may be formed at deposition pressures that facilitate the formation of the regions. In embodiments the GaN-containing regions 325a-b may be formed at deposition pressures greater than or about 10 Torr, greater than or about 50 Torr, greater than or about 100 Torr, greater than or about 200 Torr, greater than or about 300 Torr, greater than or about 400 Torr, greater than or about 500 Torr, greater than or about 600 Torr, greater than or about 700 Torr, or more.

In embodiments, the GaN-containing regions 325a-b may be formed with a pyramidal shape. In further embodiments, the base of the pyramid may be in contact with the nucleation layer 310, while the apex of the pyramid may point in a direction opposite the nucleation layer.

Referring now to FIG. 3B, the GaN-containing regions 325a-b formed in operation 220 may be annealed in operation 225. In embodiments, the annealing operation 225 sublimates off the apex of the pyramidal-shaped region to leave a planar region 330a-b (sometimes called a c-facet) at the top of the GaN-containing regions 325a-b. The planar region 330a-b can create a stable base for the formation of subsequent components of a subpixel, including a compliant layer and an active region.

The annealing operation 225 may include heating the GaN-containing regions 325a-b in annealing gases for a designated period of time. In embodiments, the GaN-containing regions 325a-b may be annealed at an annealing temperature greater than or about 900° C., greater than or about 1000° C., greater than or about 1100° C., or more. In further embodiments, the GaN-containing regions 325a-b may be annealed in one or more annealing gases that may include at least one of ammonia or hydrogen (H₂). In still further embodiments, the GaN-containing regions 325a-b may be annealed for less than or about 10 minutes, less than or about 7.5 minutes, less than or about 5 minutes, or less.

FIGS. 3C-D illustrate an embodiment of the present technology where InGaN-containing layers each having at least two portions are formed on the GaN-containing regions 325a-b. First portions of the InGaN-containing layers 335a-b may be porosified to form porosified regions in the subpixels. Second portions of the InGaN-containing layers 340a-b may be the active regions 340a-b of the subpixels where light is generated. It will be appreciated that the present technology contemplates additional embodiments, including embodiments where a portion of the GaN-containing regions 325a-b are formed into porosified regions. In still further embodiments, porosified regions may be formed from portions of both the InGaN-containing layers 335a-b and the GaN-containing regions 325a-b.

Referring now to FIG. 2 and FIG. 3C, method 200 may further include the formation of indium-gallium-nitrogen (InGaN)-containing layers 335a-b at operation 230. In embodiments, these layers may be formed in a bottom-up manner by first depositing and patterning a mask layer (not shown) on the annealed GaN-containing regions 325a-b. In further embodiments, the patterned mask layer may include openings to reveal exposed portions of the annealed GaN-containing regions 325a-b. In yet further embodiments, a blanket film of the InGaN-containing material may be deposited on the patterned mask layer. In still further embodiments, excess material in the InGaN-containing blanket film may be removed to form the InGaN-containing layers 335a-b. Embodiments of the removal processes may include annealing and/or chemical-mechanical polishing of the as-deposited InGaN-containing blanket film. In embodiments, the formation of the InGaN-containing layers 335a-b avoid sidewall etching of the segments and the subsequently-formed active regions of the layers. This reduces at least a portion of the roughness and dislocations in the sidewalls that can create non-radiative sinks for the electrical current energy and reduce conversion efficiency.

In embodiments, the InGaN-containing layers 335a-b may be formed with MOCVD using the same or similar precursors and deposition conditions used to form the GaN-containing regions 325a-b. In further embodiments, the mole percentage of indium in the InGaN-containing layers 335a-b may be greater than or about 5 mol. %, greater than or about 6 mol. %, greater than or about 7 mol. %, greater than or about 8 mol. %, greater than or about 9 mol. %, greater than or about 10 mol. %, or more. In still additional embodiments, the amount of indium in the InGaN-containing layers 335a-b may be the same as the amount of indium in the GaN-containing regions 325a-b. Under some conditions, when the mole percentage of indium in the InGaN-containing layers 335a-b is similar to or the same as the mole percentage of indium in the GaN-containing regions 325a-b, the defects and stress in the InGaN-containing layers 335a-b may be substantially reduced. In still further embodiments, the amount of indium in the InGaN-containing layers 335a-b may be an intermediate amount between the amount of indium in the GaN-containing regions 325a-b, and the amount of indium in subsequently-formed active regions of the InGaN-containing layers. In these embodiments, the InGaN-containing layers 335a-b may help bridge the transition from the lower amounts of indium in the GaN-containing regions 325a-b to the higher amounts of indium in the active regions.

In embodiments, the formation of the InGaN-containing layers 335a-b may further include the incorporation of one or more porosity dopants into a portion of the layers to form a doped region. The porosity dopants may increase a rate which porosity etchants can form pores in the doped regions. The porosity dopant level may be used to adjust the amount of porosity formed in the doped regions. In additional embodiments, the porosity dopants may include silicon (Si) incorporated into a portion of at least one of the GaN-containing regions 325a-b and the InGaN-containing layers 335a-b. In embodiments, the amount of incorporated silicon may be greater than or about 5×10¹⁷ atoms/cm³, greater than or about 1×10¹⁸ atoms/cm³, greater than or about 2×10¹⁸ atoms/cm³, greater than or about 3×10¹⁸ atoms/cm³, greater than or about 4×10¹⁸ atoms/cm³, greater than or about 5×10¹⁸ atoms/cm³, greater than or about 6×10¹⁸ atoms/cm³, greater than or about 7×10¹⁸ atoms/cm³, greater than or about 8×10¹⁸ atoms/cm³, greater than or about 9×10¹⁸ atoms/cm³, greater than or about 1×10¹⁹ atoms/cm³, or more.

In embodiments, the porosified regions may be formed at operation 235. Embodiments of the porosification operation 235 may include an electrochemical etch process that exposes the doped regions to an electrochemical etchant while a voltage is applied to the one or more segments. In additional embodiments, the electrochemical etchant may be an acid such as oxalic acid or sulfuric acid. In further embodiments, the electrochemical etchant may be a base such as potassium hydroxide. In further embodiments, the voltage applied to the doped regions to be porosified may be greater than or about 1 volt, greater than or about 5 volts, greater than or about 10 volts, greater than or about 12.5 volts, greater than or about 15 volts, greater than or about 17.5 volts, greater than or about 20 volts, greater than or about 22.5 volts, greater than or about 25 volts, greater than or about 27.5 volts, greater than or about 30 volts, or more.

In embodiments, the porosification operation 235 may increase the void fraction the porosified region. In additional embodiments, a porosified region may be characterized by a void fraction greater than or about 10 vol. %, greater than or about 15 vol. %, greater than or about 20 vol. %, greater than or about 25 vol. %, greater than or about 30 vol. %, greater than or about 35 vol. %, greater than or about 40 vol. %, greater than or about 45 vol. %, greater than or about 50 vol. %, greater than or about 55 vol. %, greater than or about 60 vol. %, or more. The increased porosity of the porosified region may make its lattice structure more compliant with the formation of a subsequently-deposited active layer that may be loaded with a significantly higher molar percentage of indium, among other differences. The more compliant porosified regions may create fewer defects and less stress in the subsequently-deposited active region, which may significantly increase the quantum efficiency of the active layer to convert the energy of electrical current into light.

Embodiments of porosification operation 235 may include the adjustment of one or more porosification parameters for different doped regions to provide different levels of added porosity to each region or subset of regions. In further embodiments, one or more porosification parameters such as the doping level of a porosity dopant in each doped region, the electrochemical etching voltage applied to each doped region, and the selective masking of doped regions may be used to vary the amount of added porosity for different porosified regions. In the embodiment shown in FIG. 3C, the a first porosified region has less added porosity than a second porosified region. In further embodiments, the first porosified region may be characterized by a void fraction less than or about 30 vol. %, less than or about 25 vol. %, less than or about 20 vol. %, less than or about 15 vol. %, less than or about 10 vol. %, less than or about 5 vol. %, less than or about 1 vol. %, or less. In embodiments, the first porosified region may be used as a less-porous compliant region for a blue-light-emitting subpixel while the second porosified region may be used as a more-porous compliant region for a red-light-emitting subpixel. An additional porosified region (not shown) may have a level of porosity between the first and second porosified regions, and may be used as an intermediately-porous compliant region for a green-light-emitting subpixel.

In embodiments, the porosification of the one or more porosified regions may be done before the deposition of the active regions as part of a bottom-up manner of fabricating the device 300. This permits the active regions to avoid some of the damage and contamination that may occur during porosification and further increase quantum efficiency for the device 300. In further embodiments (not shown) a portion of the GaN-regions 325a-b may be porosified by the same operations described for porosifying the InGaN-containing layers 335a-b.

Method 200 may still further include an operation 240 to form active regions for converting energy from a supplied electrical current into light. As illustrated in FIG. 3D, the active regions 340a-b may be formed in a portion of the the InGaN-containing layers 335a-b, and may be formed with different molar percentages of indium to permit them to generate light at different wavelengths. In embodiments, the active regions 340a-b may be formed by a bottom-up process that may include first forming an patterning a mask layer (not shown) on the porosified regions. In further embodiments, InGaN-containing material may be deposited on the patterned mask layer. In still further embodiments, excess InGaN material may be removed to form the InGaN-containing active regions 340a-b. Embodiments of the removal processes may include chemical-mechanical polishing, subtractive etch, and/or liftoff of the as-deposited, excess InGaN-containing material, among other removal processes. In embodiments, the formation of the active regions 340a-b avoid sidewall etching of these regions as well as the previously-formed porosified regions. This reduces at least a portion of the roughness and dislocations in the sidewalls that can create non-radiative sinks for the electrical current energy and reduce conversion efficiency.

In embodiments, the active region 340a may have a molar percentage of indium that is less than or about 15 mol. %, less than or about 14 mol. %, less than or about 13 mol. %, less than or about 12 mol. %, less than or about 11 mol. %, less than or about 10 mol. %, or less. This blue-emitting active region 340a may produce light characterized by a peak intensity wavelength of less than or about 500 nm, less than or about 490 nm, less than or about 480 nm, less than or about 470 nm, less than or about 460 nm, less than or about 450 nm, less than or about 440 nm, less than or about 430 nm, less than or about 420 nm, less than or about 410 nm, less than or about 400 nm, or less. In further embodiments, the active region 340b may have a molar percentage of indium that is greater than or about 30 mol. %, greater than or about 31 mol. %, greater than or about 32 mol. %, greater than or about 33 mol. %, greater than or about 34 mol. %, greater than or about 35 mol. %, greater than or about 36 mol. %, greater than or about 37 mol. %, greater than or about 38 mol. %, greater than or about 39 mol. %, greater than or about 40 mol. %, or more. This red-emitting active region 340b may produce light characterized by a peak intensity wavelength of greater than or about 600 nm, greater than or about 610 nm, greater than or about 620 nm, greater than or about 630 nm, greater than or about 640 nm, greater than or about 650 nm, greater than or about 660 nm, greater than or about 670 nm, greater than or about 680 nm, greater than or about 690 nm, or more.

It will be appreciated that embodiments of device 300 may further include a green-light subpixel (not shown) that has the same components of a GaN-containing region, porosified region, and InGaN-containing active region as shown for the blue-light and red-light emitting subpixels. In embodiments, this green-light subpixel may include a porosified region having a porosity that is intermediate between the blue- and red-light subpixels. In further embodiments, the green-light subpixel may have an active region with a molar percentage of indium that is greater than or about 20 mol. %, and less than or about 25 mol. %. The active region of an exemplary green-light subpixel may produce light characterized by a peak intensity wavelength of about 530 nm.

In embodiments, the method 200 may produce a red-light subpixel having an active region with a higher quantum efficiency than produced with conventional, top-down fabrication methods. In embodiments, the external quantum efficiency of the red-emitting active region 340b may be greater than or about 0.1%, greater than or about 0.2%, greater than or about 0.3%, greater than or about 0.4%, greater than or about 0.5%, greater than or about 0.6%, greater than or about 0.7%, greater than or about 0.8%, greater than or about 0.9%, greater than or about 1%, greater than or about 5%, greater than or about 10%, greater than or about 20%, greater than or about 30%, greater than or about 40%, greater than or about 50%, greater than or about 60%, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a trench” includes a plurality of such trenches, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a nucleation layer on a semiconductor substrate;
forming a GaN-containing region on the nucleation layer;
forming an InGaN-containing layer on the GaN-containing region; and
porosifying a portion of at least one of the GaN-containing region and the InGaN-containing layer to form a porosified region,
wherein the InGaN-containing layer includes an active region on the porosified region, and wherein the active region comprises a greater mol. % indium than the porosified region.

2. The semiconductor processing method of claim 1, wherein the GaN-containing region is formed by selective area growth of GaN-containing material on exposed portions of the nucleation layer.

3. The semiconductor processing method of claim 2, wherein the GaN-containing region is annealed to form a planar facet in the GaN-containing region, and wherein the InGaN-containing layer is formed on the planar facets of the GaN-containing region.

4. The semiconductor processing method of claim 1, wherein the porosified region is formed by contacting the portion of at least one of the GaN-containing region and the InGaN-containing layer with an electrochemical etchant.

5. The semiconductor processing method of claim 1, wherein the porosified region is characterized by a void fraction of greater than or about 20 vol. %.

6. The semiconductor processing method of claim 1, wherein the active region is characterized by an amount of indium greater than or about 30 mol. %.

7. The semiconductor processing method of claim 1, wherein the active region is characterized by a peak light emission at a wavelength of greater than or about 620 nm.

8. The semiconductor processing method of claim 1, wherein the semiconductor is a light emitting diode characterized by an external quantum efficiency of greater than or about 0.2%.

9. A semiconductor processing method comprising:
forming a GaN-containing region on a substrate;
forming an InGaN-containing layer on the GaN-containing region,
forming a porosified region on a portion of at least one of the GaN-containing region and the InGaN-containing layer, wherein the porosified region is characterized by a void fraction of greater than or about 20 vol. %, and
wherein the InGaN-containing layer includes an active region that is characterized by a peak light emission at a wavelength of greater than or about 620 nm.

10. The semiconductor processing method of claim 9, wherein the porosified region is formed by electrochemically etching a silicon-doped region in at least one of the GaN region and the InGaN-containing layer.

11. The semiconductor processing method of claim 10, wherein the silicon-doped region is characterized by a silicon amount greater than or about 5×10¹⁷ atoms/cm³.

12. The semiconductor processing method of claim 10, wherein the silicon-doped region is electrochemically etched with an etchant comprising an acid.

13. The semiconductor processing method of claim 12, wherein the acid comprises oxalic acid.

14. The semiconductor processing method of claim 9, wherein the GaN-containing region is formed by selective area growth and annealing of an as-deposited GaN-containing material.

15. A semiconductor structure comprising:
a first subpixel comprising:
a GaN-containing region in contact with a nucleation layer formed between the GaN-containing region and a substrate;
a porous region in contact with the GaN-containing region; and
an active region in contact with the porous region, wherein the active region is characterized by an amount of indium greater than or about 30 mol. %.

16. The semiconductor structure of claim 15, wherein the nucleation layer comprises a AlN layer, a NbN layer, a TiN layer, or an HfN layer.

17. The semiconductor structure of claim 15, wherein the GaN-containing region lacks parallel sidewalls.

18. The semiconductor structure of claim 15, wherein the semiconductor structure further comprises a second subpixel comprising a second active region characterized by an amount of indium less than or about 25 mol. %, and a third subpixel comprising a third active region characterized by an amount of indium less than or about 15 mol. %.

19. The semiconductor structure of claim 15, wherein the active region is characterized by a peak light emission at a wavelength of greater than or about 620 nm, and an external quantum efficiency of greater than or about 0.2%.

20. The semiconductor structure of claim 15, wherein the semiconductor structure is a light emitting diode.
